(19) United States
(12) Patent Application Publication
(10) Pub. No.: US 2012/0198306 A1
(43) Pub. Date: Aug. 2, 2012

(54) METHOD AND APPARATUS FOR TRANSMITTING AND RECEIVING IN COMMUNICATION/BROADCASTING SYSTEM

(75) Inventors: Se-Ho MYUNG, Suwon-si (KR); Hyun-Koo YANG, Seoul (KR); Hong-Sil JEONG, Seoul (KR)

(73) Assignee: Samsung Electronics Co., Ltd

(21) Appl. No.: 13/363,002

(22) Filed: Jan. 31, 2012

(30) Foreign Application Priority Data
Jan. 31, 2011 (KR) 10-2011-0009674

(51) Int. Cl. H03M 13/09; G06F 11/10; H03M 13/05

(52) U.S. Cl. 714/758; 714/800; 714/E11.032

(57) ABSTRACT

An apparatus and method are provided for transmitting and receiving in a communication/broadcasting system. The method includes generating a codeword including a first parity bit using a first parity-check matrix, generating an additional parity bit based on a second parity-check matrix, the second parity-check matrix being an extension of the first parity-check matrix, and transmitting the codeword and the additional parity bit.

### PRIORITY

The application claims priority under 35 U.S.C. §119(a) to Korean patent application Serial No. 10-2011-0009674, which was filed in the Korean Intellectual Property Office on Jan. 31, 2011, the entire disclosure of which is hereby incorporated by reference.

### BACKGROUND OF THE INVENTION

1. Field of the Invention

The present invention relates to a communication/broadcasting system utilizing a linear code based on a parity-check matrix.

2. Description of the Related Art

A communication/broadcasting system performs channel coding in order to correct an error occurring in a channel.

Next-generation communication/broadcasting systems require a transmission method that maximizes system capacity and also meets the demands of various users. For this, the channel coding should be performed using codes having different code rates and codeword lengths. If the flexibility of these codes increases, an Adaptive Modulation and Coding (AMC) technique or a Hybrid Automatic Retransmission reQuest (HARQ) application becomes easier, and the next-generation communication/broadcasting systems can support different code rates and codeword lengths using one COder/DECoder (CODEC), thereby reducing hardware complexity.

Accordingly, there is a need for a method and apparatus for efficiently supporting multiple code rates or multiple codewords in a communication/broadcasting system.

### SUMMARY OF THE INVENTION

Accordingly, the present invention has been made to solve at least the above-described problems and/or disadvantages and to provide at least the advantages described below.

Accordingly, an aspect of the present invention is to provide a method and apparatus for transmitting and receiving in a communication/broadcasting system.

Another aspect of the present invention is to provide an efficient channel encoding/decoding method and apparatus for supporting different code rates and different codeword lengths in a communication/broadcasting system.

In accordance with an aspect of the present invention, a method for transmitting in a communication/broadcasting system is provided. The method includes generating a codeword including a first parity bit using a first parity-check matrix; generating an additional parity bit based on a second parity-check matrix, the second parity-check matrix being an extension of the first parity-check matrix; and transmitting the codeword and the additional parity bit.

In accordance with another aspect of the present invention, a method for receiving in a communication/broadcasting system is provided. The method includes receiving a codeword from a transmitter; and decoding the codeword based on a first parity-check matrix and an additional parity bit. The additional parity bit is based on a second parity-check matrix, the second parity-check matrix being an extension of the first parity-check matrix.

In accordance with another aspect of the present invention, an apparatus for transmitting in a communication/broadcasting system is provided. The apparatus includes a parity-check matrix provider for extending a first parity-check matrix and deciding a second parity-check matrix; an encoder for generating a codeword including a first parity bit utilizes the first parity-check matrix, and deciding a second parity bit based on the second parity-check matrix, to generate an additional parity bit; and a transmitter for transmitting the generated codeword and the additional parity bit.

In accordance with another aspect of the present invention, an apparatus for receiving in a communication/broadcasting system is provided. The apparatus includes a receiver for receiving a codeword including a first parity bit from a transmitter; and a decoder for decoding the codeword based on a first parity-check matrix and an additional parity bit.

### BRIEF DESCRIPTION OF THE DRAWINGS

The above and other aspects, features, and advantages of the present invention will be more apparent from the following description taken in conjunction with the accompanying drawings, in which:

FIG. 1 illustrates a parity-check matrix according to an embodiment of the present invention;

FIG. 2 illustrates a parity-check matrix where N₁=30, K₁=15, M₁=5, q₁=1, according to an embodiment of the present invention;

FIG. 3 illustrates a parity-check matrix having a 1st weight-1 sequence of N₁=32, K₁=12, M₁=4, q₁=5, according to an embodiment of the present invention;

FIG. 4 illustrates an extended parity-check matrix according to an embodiment of the present invention;

FIG. 5 is a flowchart illustrating a channel encoding method in a communication/broadcasting system using a Low Density Parity Check (LDPC) code according to an embodiment of the present invention;

FIG. 6 is a flowchart illustrating a channel encoding method in a communication/broadcasting system using an LDPC code according to an embodiment of the present invention;

FIG. 7 is a flowchart illustrating a channel encoding method using a linear code based on a parity-check matrix in a communication/broadcasting system using an LDPC code according to an embodiment of the present invention;

FIG. 8 is a flowchart illustrating a weight-1 position sequence conversion process according to an embodiment of the present invention;

FIG. 9 is a flowchart illustrating a channel decoding method using a linear code based on a parity-check matrix in a communication/broadcasting system using an LDPC code according to an embodiment of the present invention;

FIG. 10 is a block diagram illustrating a transmitter according to an embodiment of the present invention;

FIG. 11 is a block diagram illustrating a receiver according to an embodiment of the present invention; and

FIG. 12 is a block diagram illustrating a parity-check matrix provider for a weight-1 position sequence conversion process according to an embodiment of the present invention.

### DETAILED DESCRIPTION OF EMBODIMENTS OF THE INVENTION

Various embodiments of the present invention are described in detail below with reference to the accompanying drawings. In the drawings, the same or similar components may be designated by the same or similar reference numerals. Detailed descriptions of constructions or processes known in the art are omitted to avoid obscuring the subject matter of the present invention. Further, the terms described below, which are defined in considering the functionality of the present invention, can be different depending on user and/or operator intention or practice.

In accordance with an embodiment of the present invention, a method is provided for converting a parity-check matrix and generating additional parity in a communication and broadcasting system using an LDPC code. Additionally, a method and apparatus are provided for encoding/decoding using the converted parity-check matrix.

Generally, assuming that a parity-check matrix ‘H’ or generator matrix ‘G’ of a parity-check code is given and an information word of a length ‘K’ composed of information bits of ‘K’ number is ‘m=(m₀, m₁, . . . , m_{K-1})’, then a relation of m·G=c, H·c^{T}=0 is satisfied. Here, ‘c’ denotes a codeword obtained from a message ‘m’.

Also, when a codeword of a given linear code is a systematic code, the codeword ‘c’ is expressed as ‘c=(m,p)’. Here, ‘p’ denotes parity. Generally, assuming that a message length (i.e., an information word length) is ‘K’ and a codeword length is ‘N’, a parity length is ‘(N−K)’ and, for full rank, the size of the parity-check matrix ‘H’ is ‘(N−K)×N’.

An example of a systematic code, i.e., a parity-check matrix ‘H’, is shown below in Equation (1).

$$H = [ \begin{matrix}1 & 1 & 1 & 0 & 1 & 0 & 0 \\ 1 & 1 & 0 & 1 & 0 & 1 & 0 \\ 1 & 0 & 1 & 1 & 0 & 0 & 1\end{matrix} ] \qquad ( 1 )$$

A codeword (c) corresponding to the parity-check matrix ‘H’ is constructed as ‘c=(m,p)’ from an information word ‘m=(m₀, m₁, m₂, m₃)’ composed of four information bits and parity ‘p=(p₀, p₁, p₂)’ composed of three parity bits. The codeword (c) is defined as shown in Equation (2) below.

$$H \cdot {\underline{c}}^{T} = [ \begin{matrix}1 & 1 & 1 & 0 & 1 & 0 & 0 \\ 1 & 1 & 0 & 1 & 0 & 1 & 0 \\ 1 & 0 & 1 & 1 & 0 & 0 & 1\end{matrix} ] [ \begin{matrix}{m}_{0} \\ {m}_{1} \\ {m}_{2} \\ {m}_{3} \\ {p}_{0} \\ {p}_{1} \\ {p}_{2}\end{matrix} ] = \underline{0} \qquad ( 2 )$$

If Equation (2) above is arranged as shown in Equation (3) below, it can be appreciated that each row of the parity-check matrix ‘H’ represents an algebraic relational equation. Each relational equation is called a parity-check equation.

$$[ \begin{matrix}{m}_{0} + {m}_{1} + {m}_{2} + {p}_{0} \\ {m}_{0} + {m}_{1} + {m}_{3} + {p}_{1} \\ {m}_{0} + {m}_{2} + {m}_{3} + {p}_{2}\end{matrix} ] = [ \begin{matrix}0 \\ 0 \\ 0\end{matrix} ] \qquad ( 3 )$$

An element not being ‘0’ in a parity-check matrix is called a weight. In a parity-check code, as the number of weights increases, an encoding and decoding complexity increases. That is, in the whole parity-check matrix, as a weight rate decreases, the complexity decreases. Generally, a parity-check code of a very low weight rate is called a Low-Density Parity-Check (LDPC) code. In many cases, the LDPC code has a characteristic in which a weight density decreases as a codeword length increases.

The parity-check code can be defined in many different forms according to the requirements of a communication/broadcasting system.

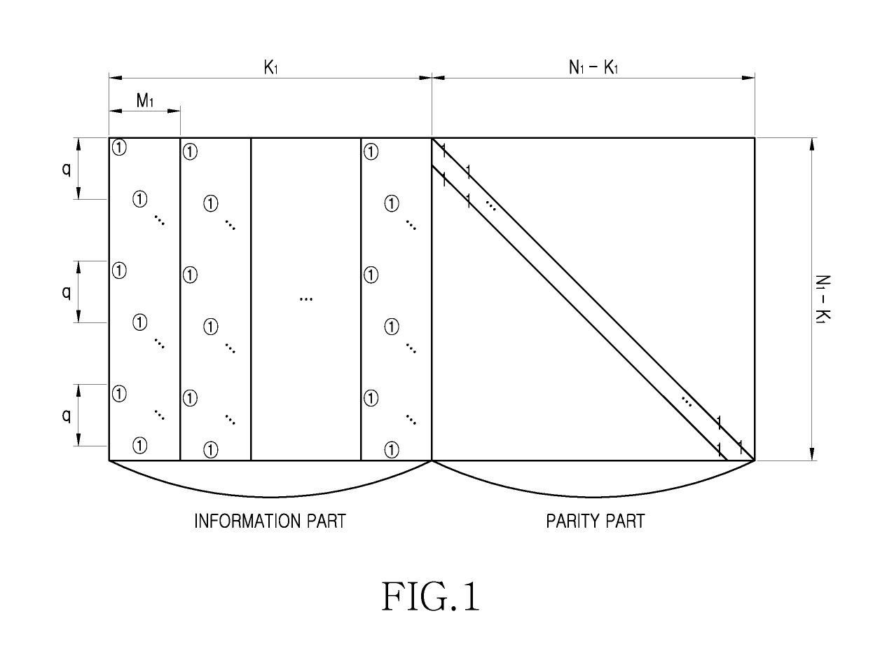

FIG. 1 illustrates a parity-check matrix according to an embodiment of the present invention.

Referring to FIG. 1, ‘N₁’ and ‘K₁’ each denote a codeword length and an information word length of a parity-check code, and ‘(N₁−K₁)’ denotes a parity length.

In the parity-check matrix, a part matrix associated with parity, i.e., a structure of K₁th column to (N₁−1) th column is of a dual-diagonal form. Accordingly, the numbers of weights of columns corresponding to the part matrix associated with the parity are all equal to ‘2’, except for the last column, which becomes ‘1’.

Further, a part matrix associated with an information word, i.e., a 0th column to a (K₁−1) th column includes columns that are grouped in the unit of columns of ‘M₁’ number. Here, ‘M₁’ is one of the key parameters of the parity-check matrix illustrated FIG. 1, and can have a value changing according to a given communication/broadcasting system.

The part matrix associated with the information word includes columns that are grouped in units of ‘M₁’ columns. If a position of a row at which a weight ‘1’ exists at a 0th column within each column group is decided, a position of a row at which a weight ‘1’ exists at an i th column within each column group is cyclic shifted as much as ‘i·q₁ mod(N₁−K₁)’ from the position of the row at which the weight ‘1’ exists at the 0th column within the each column group. Here, ‘q₁’ is an integer, which satisfies ‘q₁=(N₁−K₁)/M₁’.

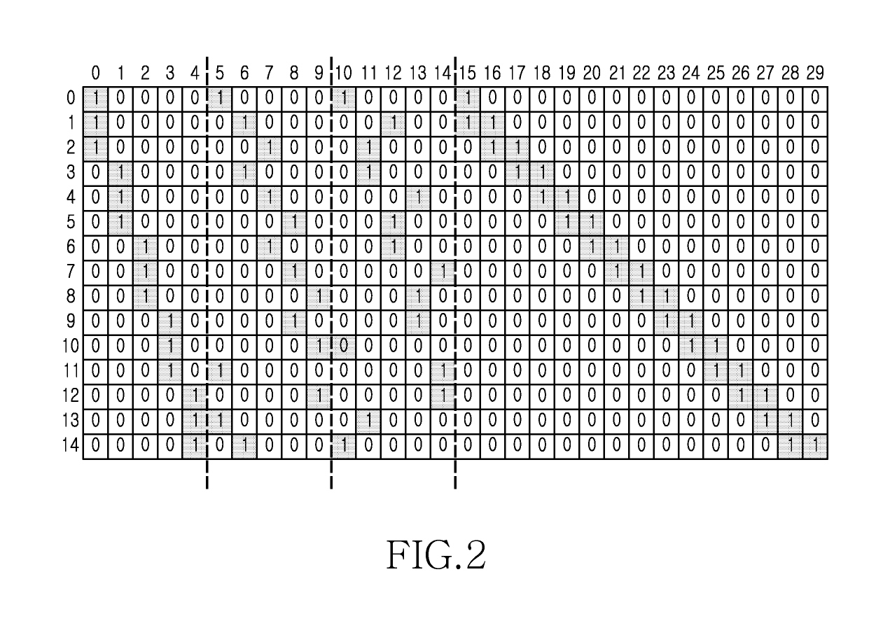

For example, in a parity-check matrix as illustrated in FIG. 1 having N₁=30, K₁=15, M₁=5, q₁=1 and expressing as follows position information of a row having a weight-1 for each of 0th columns of three column groups is illustrated in FIG. 2.

$$\begin{matrix}0 & 1 & 2 \\ 0 & 11 & 13 \\ 0 & 10 & 14\end{matrix}$$

An i^{th} weight-1 position sequence is expressed by an index of a row in which a weight-1 is positioned in a 0^{th} column belonging to an i^{th} column group. Where, “0 1 2” means that the 0th, 1st, and 2nd row of 0th column (the first column in the first column group) is filled with ‘1’, “0 11 13” means that the 0th, 11th, and 13th of 5th column (the first column in the second column group) is filled with ‘1’ and “0 10 14” means that the 0th, 10th, and 14th of the 10th column (the first column in the third column group) is filled with ‘1’ in the parity-check matrix of FIG. 2.

Here, the sequence is called a weight-1 position sequence. A j th (j=0, 1, . . . , (K₁/M₁−1)) sequence, i.e., a j th weight-1 position sequence, is a sequential expression of position information of a row at which a weight-1 is positioned at a 0th column within a j th column group.

FIG. 2 illustrates a parity-check matrix where N₁=30, K₁=15, M₁=5, q₁=1 according to an embodiment of the present invention.

Referring to FIG. 2, in the first column group including a 0th column to a 4th column, rows at which weight-1 are positioned at the 0th column corresponding to the first column within the first column group are rows 0, 1, and 2. Also, rows at which weight-1 are positioned at the 1st column corresponding to the second column within the first column group are rows 3 (=(0+q₁)mod(N₁−K₁)), 4(=(1+q₁)mod(N₁−K₁)), and 5(=(2+q₁)mod(N₁−K₁)). Further, rows at which weight-1 are positioned at the 3rd column corresponding to the fourth column within the first column group are rows 9(=(0+3×q₁)mod(N₁−K₁)), 10(=(1+3×q₁)mod(N₁−K₁)), and 11(=(2+3×qᵢ)mod(N₁−K₁)).

In the second column group including a 5th column to a 9th column, rows at which weight-1 are positioned at the 5th column corresponding to the first column within the second column group are rows 0, 11, and 13. Rows at which weight-1 are positioned at the 6th column corresponding to the second column within the second column group are rows 3(=(0+q₁)mod(N₁−K₁)), 14(=(11+q₁)mod(N₁−K₁)), and 1(=(13+q₁)mod(N₁−K₁)). Also, rows at which weight-1 are positioned at the 9th column corresponding to the fifth column within the second column group are rows 12(=(0+4×q₁)mod(N₁−K₁)), 8(=(11+4×q₁)mod(N₁−K₁)), and 10(=(13+4×q₁)mod(N₁−K₁)). Likewise, this feature can be easily confirmed even in the other column groups.

In the following description, it is assumed that a codeword of the parity-check code associated with the parity-check matrix ‘H’ of Equation 1 is expressed as ‘c=(m₀, m₁, m₂, m₃, p₀, p₁, p₂)’ and ‘c’ is transmitted to a receiving end in a communication/broadcasting system using the parity-check code.

The receiving end may fail to decode an information word ‘m’ from a received signal. Therefore, in accordance with an embodiment of the present invention, additional parity is transmitted, which is combined with the codeword ‘c’, to decode the information word ‘m’.

In accordance with an embodiment of the present invention, a method is proposed for identifying hidden intermediate variables from a given parity-check matrix and a previously transmitted codeword, and utilizing the intermediate values as an additional parity in a communication/broadcasting system.

Equation (4) shows three parity-check equations that are obtainable from Equation (3).

m₀+m₁+m₂+p₀=0

m₀+m₁+m₃+p₁=0

m₀+m₂+m₃+p₂=0 (4)

In Equation (4), ‘m₀+m₁+m₂+p₀=0’ is equivalent to ‘m₀+p₀=m₁+m₂’ and ‘m₀+m₁+m₃+p₁=0’ is equivalent to ‘m₀+m₃=m₁+p₁’. Accordingly, the first and second parity-check equations of Equation 4, i.e., m₀+m₁+m₂+p₀=0 and m₀+m₁+m₃+p₁=0, can be expressed as shown in Equation (5) below introducing intermediate variables (y₀, y₁).

$$\begin{matrix}\begin{matrix}\begin{matrix} \\ \end{matrix} \\ {y}_{0} = {m}_{0} + {p}_{0} = {m}_{1} + {m}_{2} = 0\end{matrix} \\ {y}_{1} = {m}_{0} + {m}_{3} = {m}_{1} + {p}_{1} = 0\end{matrix} ⇔ \{ \begin{matrix}{y}_{0} = {m}_{0} + {p}_{0} \\ {y}_{0} = {m}_{1} + {m}_{2} \\ {y}_{1} = {m}_{0} + {m}_{3} \\ {y}_{1} = {m}_{1} + {p}_{1}\end{matrix} \qquad ( 5 )$$

Equation (6) shows Equations (4) and (5) expressed as parity-check equations regarding each of the intermediate variables (y₀, y₁) as a parity bit.

$$[ \begin{matrix}{m}_{0} + {p}_{0} + {y}_{0} \\ {m}_{1} + {m}_{2} + {y}_{0} \\ {m}_{1} + {p}_{1} + {y}_{1} \\ {m}_{0} + {m}_{3} + {y}_{1} \\ {m}_{0} + {m}_{2} + {m}_{3} + {p}_{2}\end{matrix} ] = [ \begin{matrix}0 \\ 0 \\ 0 \\ 0 \\ 0\end{matrix} ] \qquad ( 6 )$$

In Equation (6), there is no change of values of ‘m₀, m₁, m₂, m₃, p₀, p₁, p₂’ despite the introduction of the intermediate variables (y₀, y₁). Also, Equation (6) can be expressed as a multiplication of a matrix, as shown in Equation (7).

$$\underline{0} = [ \begin{matrix}1 & 0 & 0 & 0 & 1 & 0 & 0 & 1 & 0 \\ 0 & 1 & 1 & 0 & 0 & 0 & 0 & 1 & 0 \\ 0 & 1 & 0 & 0 & 0 & 1 & 0 & 0 & 1 \\ 1 & 0 & 0 & 1 & 0 & 0 & 0 & 0 & 1 \\ 1 & 0 & 1 & 1 & 0 & 0 & 1 & 0 & 0\end{matrix} ] [ \begin{matrix}{m}_{0} \\ {m}_{1} \\ {m}_{2} \\ {m}_{3} \\ {p}_{0} \\ {p}_{1} \\ {p}_{2} \\ {y}_{0} \\ {y}_{1}\end{matrix} ] = {H}_{E} \cdot {\underline{c}}_{E}^{T} \qquad ( 7 )$$

In Equation (7), ‘c_{E}’ is a codeword composed of ‘c’ and ‘y₀, y₁’. Here, a parity-check matrix for the codeword ‘c_{E}’ is ‘H_{E}’. That is, it is the same as generating an extended codeword ‘c_{E}=(c, y₀, y₁)’ in which parity (y₀, y₁) are additionally added to the firstly given codeword ‘c’.

Here, in the relationship between ‘H’ of Equation (1) and the ‘H_{E}’ of Equation (7), it can be appreciated that, when combining the first row and the second row of ‘H_{E}’, the first row of ‘H’ is obtained and, when combining the third row and the fourth row of ‘H_{E}’, the second row of ‘H’ is obtained. This is the desired result of introducing the intermediate variables (y₀, y₁) into Equations (4) and (5) above.

When rows of the parity-check matrix ‘H_{E}’ are suitably added to each other, the firstly given parity-check matrix ‘H’ can be obtained as desired.

As described above, when a communication/broadcasting system uses a parity-check code for encoding/decoding, and suitable intermediate variables are introduced into a parity-check matrix of the parity-check code, as in Equations (4) and (5), the communication/broadcasting system obtains an extended parity-check matrix like the ‘H_{E}’ of Equation (7) and the introduced intermediate variables can be regarded as newly generated parity bits. Accordingly, when the communication/broadcasting system requires transmission of additional parity, the communication/broadcasting system can transmit values corresponding to the intermediate variables and perform efficient encoding/decoding.

Commonly, when a communication/broadcasting system uses additional parity, the communication/broadcasting system cannot obtain an additional coding gain until generating new additional parity, which is different from previously generated parity, rather than simply repeatedly transmitting parity. Therefore, by generating the additional parity through Equations (4) and (5), as described above, the communication/broadcasting system can obtain a coding gain effect.

Generally, when a communication/broadcasting system separates each of ‘A’ parity-check equations into two parity-check equations and obtains ‘2A’ parity-check equations in a parity-check matrix, the communication/broadcasting system can draw ‘A’ intermediate variables. For example, as shown in Equations (4), (5), and (7), when the communication/broadcasting system separates each of two parity-check equations matching with two rows into two parity-check equations in a given parity-check matrix, the total two intermediate variables are drawn.

Additionally, when separating a parity-check equation into ‘B’ parity-check equations, the communication/broadcasting system can draw ‘(B−1)’ intermediate variables.

Generally, when separating each of ‘A’ parity-check equations into ‘B’ parity-check equations and obtaining ‘A·B’ parity-check equations, the communication/broadcasting system can draw ‘A·(B−1)’ intermediate variables.

Although a description provided below will separate a parity-check equation into two parity-check equations, i.e., ‘B=2’, the present invention is not limited to using only two parity-check equations.

In accordance with an embodiment of the present invention, a method is provided for providing an efficient encoding/decoding technique by separating rows according to a specific rule for an LDPC code having the parity-check matrix as illustrated in FIG. 1.

The parity-check matrix of FIG. 1 can be defined by a weight-1 position sequence. Therefore, a weight-1 position sequence of a first given LDPC code is called a 1st weight-1 sequence.

In the parity-check matrix of the LDPC code corresponding to the 1st weight-1 sequence, when parity-check equations are suitably set to match with ‘N_{IR}’ rows and each of the parity-check equations is separated into two parity-check equations, ‘N_{IR}’ intermediate variables can be drawn, which can be regarded as N_{IR} new parity bits.

In the following <weight-1 position sequence conversion process>, a method is provided for applying suitable row separation to the parity-check matrix of the LDPC code corresponding to the 1st weight-1 sequence having key variables such as a codeword length ‘N₁’, an information word length ‘K₁’, and a column group unit ‘M₁, qᵢ=(N₁−K₁)/M₁’, and obtaining a 2nd weight-1 sequence having a parity-check matrix of the same form as illustrated in FIG. 1 and having variables such as a codeword length ‘N_{E}=(N₁+N_{IR})’, an information word length ‘K₁’, and a column group unit ‘M₁, q_{E}=(N_{E}−K₁)/M₁’. To guarantee that the ‘q_{E}’ is an integer, ‘N_{IR}/M₁F_{IR}’ (however, F_{IR}≦q₁) is set to be an integer.

For ease of description, it is assumed herein that ‘S⁽¹⁾’ denotes the 1st weight-1 sequence, and ‘S_{i,j}⁽¹⁾’ denotes a j th numeral of an i th sequence in the ‘S⁽¹⁾’. ‘i’ can be a value of ‘0’ to ‘(K₁/M₁−1)’, and ‘j_{i,max}’ defines the number of numerals in each i th sequence. ‘S⁽²⁾’ denotes the 2nd weight-1 sequence obtained through the following <weight-1 position sequence conversion process>, and ‘S_{i,j}⁽²⁾’ denotes a j th numeral of an i th sequence in the ‘S⁽²⁾’.

<Weight-1 Position Sequence Conversion Process>

A position (a₀, a₁, a₂, . . . , a_{F}_{_{IR}}₋₁) of a row corresponding to a parity-check equation to be separated in a parity-check matrix corresponding to a 1st weight-1 sequence is determined. However, each aₗ value satisfies a relation of 0≦a₀≦a₁≦ . . . ≦a_{F}_{_{IR}}₋₁<q₁.

For 0 ≦ l < F_{IR}

TEMP=0
aₗ ← (aₗ + l)
For 0 ≦ i < K₁ / M₁
For 0 ≦ j < j_{i,max}

If (S_{i,j}⁽¹⁾ > aₗ + q₁ (M₁ − 1))
S_{i,j}⁽²⁾ ← S_{i,j}⁽¹⁾ + M₁
END
For 0 ≦ k < M₁
If (S_{i,j}⁽¹⁾ > aₗ + q₁ (k − 1)) & &(S_{i,j}⁽¹⁾ ≦ aₗ + q₁ · k)

& &((S_{i,j}⁽¹⁾%q₁) ≠ aₗ)

S_{i,j}⁽²⁾ ← S_{i,j}⁽¹⁾ + k

END

Else If (S_{i,j}⁽¹⁾ > aₗ + q₁ (k − 1)) & &(S_{i,j}⁽¹⁾ ≦ aₗ + q₁ · k)

& &((S_{i,j}⁽¹⁾%q₁) = aₗ)

S_{i,j}⁽²⁾ ← S_{i,j}⁽¹⁾ + k + Temp
Temp←((Temp+1)%2)

END

END

END

```
  END
  For 0 ≦ i < k₁ / M₁
```

For 0 ≦ j < j_{i,max}

S_{i,j}⁽¹⁾ ← S_{i,j}⁽²⁾

END

```
  END
  q₁ ← (q₁ + 1)
```

END

In the <weight-1 position sequence conversion process>, the ‘%’ denotes the remnant operation, and the ‘&&’ denotes AND operation.

A sequence ‘S⁽²⁾’ composed of values ‘S_{i,j}⁽²⁾’ finally obtained from a first given 1st weight-1 sequence ‘S⁽¹⁾’ through the <weight-1 position sequence conversion process> becomes a 2nd weight-1 sequence, and a finally obtained ‘q₁’ value becomes ‘q_{E}’. Also, a parity-check matrix corresponding to the 2nd weight-1 sequence ‘S⁽²⁾’ includes ‘F_{IR}×M₁(=N_{IR})’ additional parity.

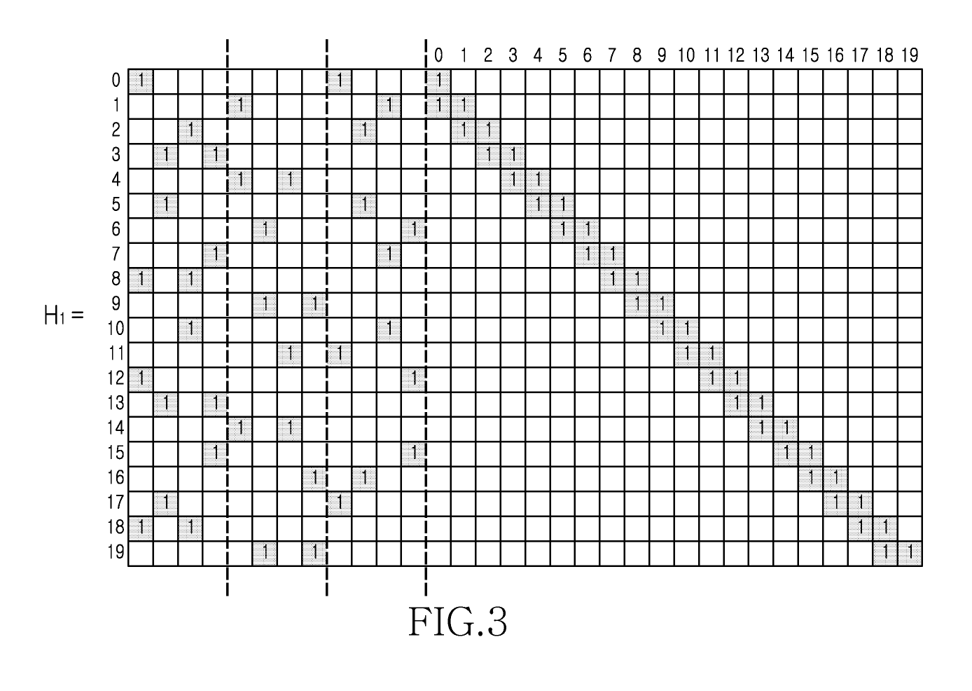

The <weight-1 position sequence conversion process> considers the parity-check matrix ‘H₁’ being N₁=32, K₁=12, M₁=4, q₁=5, as illustrated in FIG. 3, and having the following 1st weight-1 sequence.

$$\begin{matrix}0 & 8 & 12 & 18 \\ 1 & 4 & 14 & \\ 0 & 11 & 17 & \end{matrix}$$

The 1st weight-1 sequence may be expressed as S_{0,0}⁽¹⁾0, S_{0,1}⁽¹⁾=8, S_{0,2}⁽¹⁾=12, S_{0,3}⁽¹⁾=18, S_{1,0}⁽¹⁾=1, S_{1,1}⁽¹⁾=4, S_{1,2}⁽¹⁾=14, S_{2,0}⁽¹⁾=0, S_{2,1}⁽¹⁾=11, S_{2,2}⁽¹⁾=17. Also, j_{1,max}=4, j_{2,max}=3, j_{3,max}=3 can be easily appreciated.

Assuming that F_{IR}=2 and a₀=3, a₁=4 are previously decided in the <weight-1 position sequence conversion process>, the operation of the <weight-1 position sequence conversion process> is given as follows.

For 0 ≦ l < 2

TEMP=0
aₗ ← (aₗ + l)
For 0 ≦ i < 3
For 0 ≦ j < j_{i,max}

If (S_{i,j}⁽¹⁾ > aₗ + 15)
S_{i,j}⁽²⁾ ← S_{i,j}⁽¹⁾ + 4
END
For 0 ≦ k < 4
If ((S_{i,j}⁽¹⁾ > aₗ + 5(k − 1)) & &(S_{i,j}⁽¹⁾ ≦ aₗ + 5k)

& &((S_{i,j}⁽¹⁾%5) ≠ aₗ))
S_{i,j}⁽²⁾ ← S_{i,j}⁽¹⁾ + k

END

Else If (S_{i,j}⁽¹⁾ > aₗ + 5(k − 1)) & &(S_{i,j}⁽¹⁾ ≦ aₗ + 5k)

& &((S_{i,j}⁽¹⁾%5) = aₗ)

S_{i,j}⁽²⁾ ← S_{i,j}⁽¹⁾ + k + Temp
Temp←((Temp+1)%2)

END

END

END

```
  END
  For 0 ≦ i < 3
```

For 0 ≦ j < j_{i,max}

S_{i,j}⁽¹⁾ ← S_{i,j}⁽²⁾

END

```
  END
  q₁ ← (q₁ + 1)
```

END

Regarding l=0, the operation result of the <weight-1 position sequence conversion process> is arranged as follows.

$$\begin{matrix}0 & 8 & 12 & 18 \\ 1 & 4 & 14 & \\ 0 & 11 & 17 & \end{matrix} ⇒ \begin{matrix}0 & 9 & 14 & 22 \\ 1 & 5 & 17 & \\ 0 & 13 & 20 & \end{matrix}$$

$${a}_{0} = 3 , {q}_{1} = 6$$

Also, regarding l=1, the operation result of the <weight-1 position sequence conversion process> is arranged as follows.

$$\begin{matrix}0 & 9 & 14 & 22 \\ 1 & 5 & 17 & \\ 0 & 13 & 20 & \end{matrix} ⇒ \begin{matrix}0 & 10 & 16 & 25 \\ 1 & 5 & 20 & \\ 0 & 15 & 23 & \end{matrix}$$

$${a}_{1} = 4 + 1 = 5 , {q}_{1} = 7$$

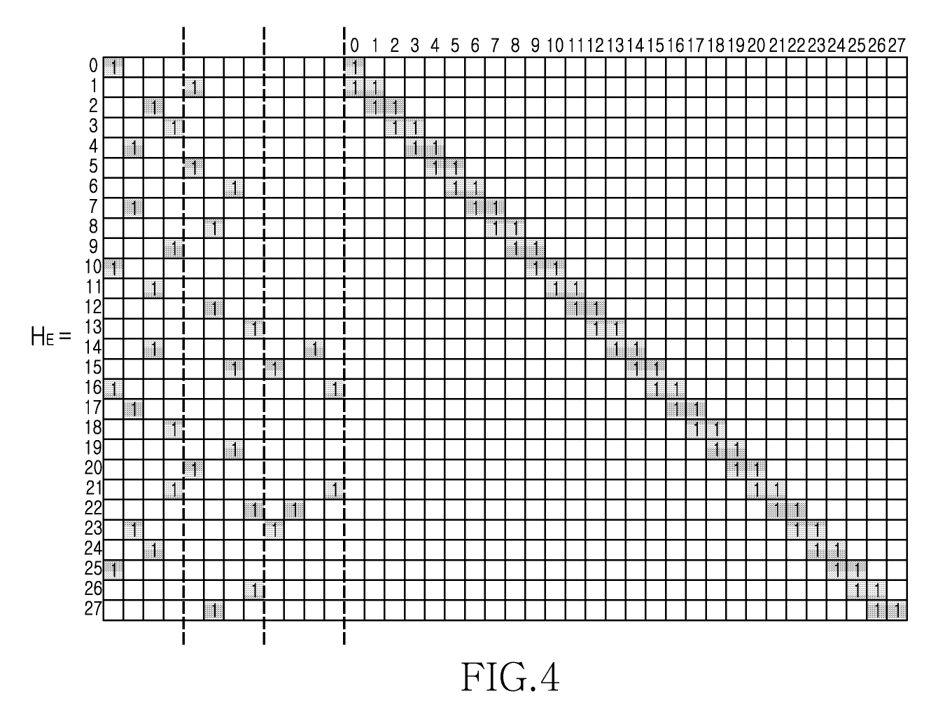

That is, the 2nd weight-1 sequence ‘S⁽²⁾’ finally obtainable through the <weight-1 position sequence conversion process> can be expressed as S_{0,0}⁽²⁾=0, S_{0,1}⁽²⁾=10, S_{0,2}⁽²⁾=16, S_{0,3}⁽²⁾=25, S_{1,0}⁽²⁾=1, S_{1,1}⁽²⁾=5, S_{1,2}⁽²⁾=20, S_{2,0}⁽²⁾=0, S_{2,1}⁽²⁾=15, S_{2,2}⁽²⁾=23. A parity-check matrix ‘H_{E}’ corresponding to the 2nd weight-1 sequence ‘S⁽²⁾’ is illustrated in FIG. 4. Key parameters of the parity-check matrix ‘H_{E}’ of FIG. 4 are N_{E}=40, K₁=12, q_{E}=7.

The parity-check matrix ‘H_{E}’ of FIG. 4 can be obtained by separating parity-check equations matching with a (3+5i)th row and a (4+5i)th row for i=0, 1, 2, 3 from the parity-check matrix ‘H₁’ of FIG. 3. Accordingly, assuming parity ‘p=(p₀, p₁, . . . , p₁₉)’ corresponding to the parity-check matrix ‘H₁’ of FIG. 3 and parity ‘p_{E}=(p_{E,0}, p_{E,1}, . . . , p_{E,27})’ corresponding to the parity-check matrix ‘H_{E}’ of FIG. 4, the following relationship is established.

Regarding i=0, 1, 2, 3, p_{E,(0+7i)}=p₀₊₅ᵢ, p_{E,(1+7i)}=p₁₊₅ᵢ, p_{E,(2+7i)}=p₂₊₅ᵢ, p_{E,(4+7i)}=p₃₊₅ᵢ, p_{E,(6+7i)}=p₄₊₅ᵢ are established, and p_{E,(3+7i)} and p_{E,(5+7i)} are newly generated parity. Accordingly, the number of newly generated parity bits is equal to 8 bits, from ‘2×4(=F_{IR}'M₁=N^{IR})’.

Generally, applying the <weight-1 position sequence conversion process> to the parity-check matrix corresponding to the 1st weight-1 sequence is equivalent to separating a parity-check equation matching with a (aⱼ+q₁·i)th row of the parity-check matrix corresponding to the 1st weight-1 sequence for a firstly given a₀, a₁, . . . , a_{F}_{_{IR}}₋₁. Here, i=0, 1, . . . , (M₁−1), j=0, 1, . . . , (F_{IR}−1). ‘a₀, a₁, . . . , a_{F}_{_{IR}}₋₁’ are values given before applying the <weight-1 position sequence conversion process>.

Additionally, assuming that parity is p_{E}=(p_{E,0}, p_{E,1}, . . . , p_{N}_{_{E}}_{-K}_{₁}₋₁) for the parity-check matrix ‘H_{E}’ corresponding to the 2nd weight-1 sequence ‘S⁽²⁾’ obtained through the <weight-1 position sequence conversion process>, F_{IR}×M₁(=N_{IR}) bits correspond to newly generated parity ‘p_{E,(a}_{ⱼ}_{+q}_{_{E}}_{·i)}’ i=0, 1, . . . , (M₁−1), j=0, 1, . . . , (F_{IR}−1), and the other bits can exactly correspond to the parity of the parity-check matrix ‘H₁’ corresponding to the 1st weight-1 sequence ‘S⁽¹⁾’, on a point-to-point basis. ‘a₀, a₁, . . . , a_{F}_{_{IR}}₋₁’ are final values after the <weight-1 position sequence conversion process> is completed.

Regarding the newly generated parity bits ‘p_{E,(a}_{ⱼ}_{+q}_{_{E}}_{·i)}’, i=0, 1, . . . , (M₁−1), j=0, 1, . . . , (F_{IR}−1), the remnant parity bits are distant from parity bits ‘p_{E,a}_{ⱼ}, j=0, 1, . . . , (F_{IR}−1) as much as a constant interval ‘q_{E}’. That is, in the parity-check matrix ‘H_{E}’ corresponding to the 2nd weight-1 sequence ‘S⁽²⁾’ obtained through the <weight-1 position sequence conversion process>, newly generated parity bits are regularly spaced apart from partial parity bits by as much as a constant interval ‘q_{E}’.

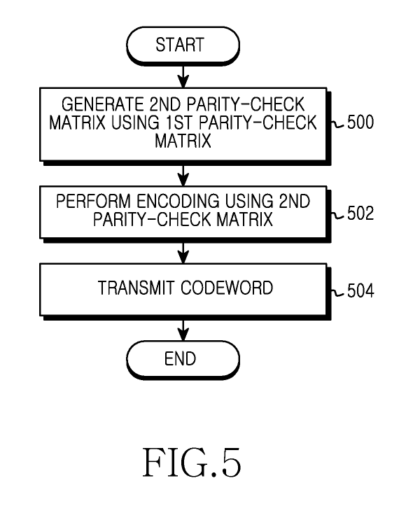

FIG. 5 is a flowchart illustrating a channel encoding method in a communication/broadcasting system using an LDPC code according to an embodiment of the present invention.

Referring to FIG. 5, in step 500, a transmitter generates a 2nd parity-check matrix ‘H_{E}’ using a 1st parity-check matrix ‘H₁’. For example, the 1st parity-check matrix ‘H₁’ can be extended into the 2nd parity-check matrix ‘H_{E}’ of FIG. 4 through the <weight-1 position sequence conversion process>. Step 500 can be repeatedly performed. For example, the transmitter can generate a 3rd parity-check matrix using the 2nd parity-check matrix ‘H_{E}’, and, likewise, can generate an Nth parity-check matrix using an (N−1)th parity-check matrix.

In step 502, the transmitter performs encoding using the generated 2nd parity-check matrix ‘H_{E}’. Assuming that the transmitter uses the 2nd parity-check matrix ‘H_{E}’ of FIG. 4, the transmitter adds 28 parity bits ‘p=(p_{E0}, p_{E1}, . . . , P_{E27})’ to 12 information bits ‘m=(m₀, m₁, . . . m₁₁)’ and encodes the bits into a codeword ‘c=(m₀, m₁, . . . , m₁₁, p_{E0}, p_{E1}, . . . , p_{E27})’ of 40 bits. When the transmitter generates the Nth parity-check matrix as described above, it is also possible to perform encoding using the Nth parity-check matrix.

In step 504, the transmitter modulates and transmits the codeword ‘c=(m₀, m₁, . . . , m₁₁, p_{E0}, p_{E1}, . . . , p_{E27})’. As described above, because the transmitter is aware of the number of added parity bits (e.g., 8 bits in FIG. 4), it is possible to transmit the added parity bits separately. That is, the transmitter can separately transmit the remnant parity bits excepting ‘p=(p₀, p₁, . . . , p₁₉)’ from the ‘p=(p_{E0}, p_{E1}, . . . , p_{E27})’ after transmitting a codeword c=(m₀, m₁, . . . , m₁₁, p₀, p₁, . . . , p₁₉).

If the transmitter generates the Nth parity-check matrix in step 500, the transmitter may separately transmit each of additional parity bits generated sequentially up to the Nth parity-check matrix.

As described above, the transmitter may separately transmit the additional parity bits in time. However, the transmitter may also separately transmit the additional parity bits in space or in frequency. For example, the transmitter may separately transmit the additional parity bits through a different frame or a different region of a specific transmission duration transmitted at an equal time, or may transmit through a different frequency band.

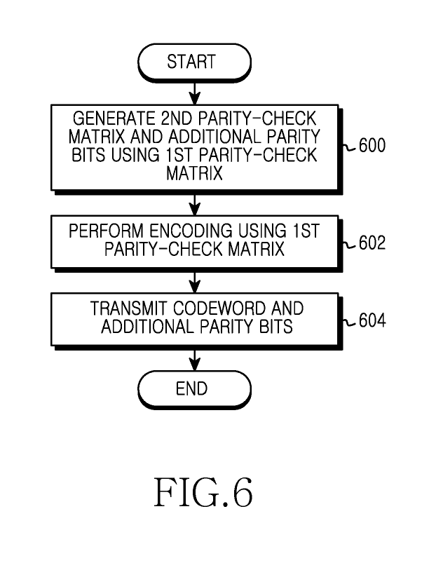

FIG. 6 is a flowchart illustrating a channel encoding method according to an embodiment of the present invention.

Referring to FIG. 6, in step 600, a transmitter generates a 2nd parity-check matrix ‘H_{E}’ and additional parity bits using a 1st parity-check matrix ‘H₁’. Step 600 can be repeatedly performed like step 500 described above, thereby generating an Nth parity-check matrix.

In step 602, the transmitter performs encoding using the 1st parity-check matrix ‘H₁’.

In step 604, the transmitter modulates and transmits a codeword ‘c=(m₀, m₁, . . . , m₁₁, p₀, p₁, . . . , p₁₉)’ and additional parity bits (i.e., the remnant parity bits except for ‘p=(p₀, p₁, . . . , p₁₉)’ from ‘p=(p_{E0}, p_{E1}, . . . , p_{E27})’). It is possible to independently or continuously transmit the additional parity bits. That is, the transmitter can separately transmits the remnant parity bits excepting the ‘p=(p₀, p₁, . . . , p₁₉)’ from the ‘p=(p_{E0}, p_{E1}, . . . , p_{E27})’ after transmitting a codeword ‘c=(m₀, m₁, . . . , m₁₁, p₀, p₁, . . . , p₁₉)’, or transmit the remnant parity bits continuously with the codeword ‘c=(m₀, m₁, . . . , m₁₁, p₀, p₁, . . . , p₁₉)’.

When the transmitter generates the Nth parity-check matrix in step 600, the transmitter may separately transmit each of additional parity bits generated sequentially up to the Nth parity-check matrix.

As described above, the transmitter may separately transmit the additional parity bits in time. However, he transmitter may also separately transmit the additional parity bits in space or in frequency. For example, the transmitter may separately transmit the additional parity bits through a different frame or a different region of a specific transmission duration transmitted at an equal time, or may transmit through a different frequency band.

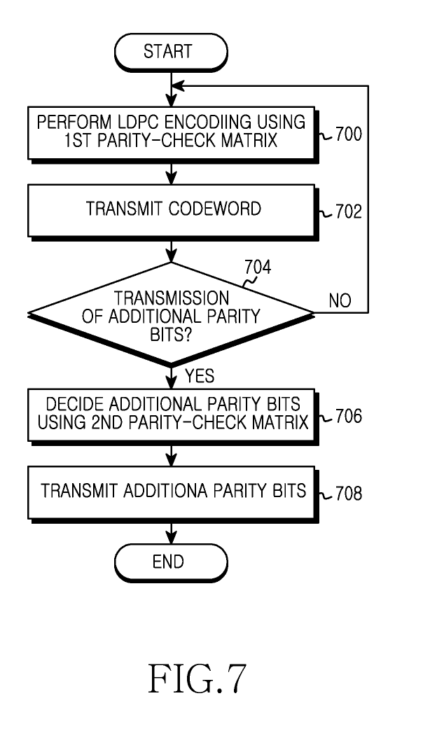

FIG. 7 is a flowchart illustrating a channel encoding method using a linear code based on a parity-check matrix in a communication/broadcasting system using an LDPC code according to an embodiment of the present invention.

Referring to FIG. 7, in step 700, a transmitter performs LDPC encoding using a 1st parity-check matrix. Here, the 1st parity-check matrix is used when there is no request for transmission of additional parity from a receiver. Assuming that the transmitter uses a 1st parity-check matrix ‘H₁’ of FIG. 3, the transmitter adds 20 parity bits ‘p=(p₀, p₁, . . . , p₁₉)’ to 12 information bits ‘m=(m₀, m₁, . . . , m₁₁)’ and encodes the bits into a codeword ‘c=(m₀, m₁, . . . , m₁₁, p₀, p₁, . . . , p₁₉)’ of 32 bits.

In step 702, the transmitter modulates and transmits the encoded codeword ‘c=(m₀, m₁, . . . , m₁₁, p₀, p₁, . . . , p₁₉)’.

In step 704, if the transmitter identifies that there is a request for transmission of additional parity for the ‘c=(m₀, m₁, . . . , m₁₁, p₀, p₁, . . . , p₁₉)’ from the receiver, the method proceeds to step 706. However, if the transmitter identifies in step 704 that there is no request for transmission of additional parity from the receiver, the method returns to step 700. The request can be performed through separate signaling. When there no separate request during a constant duration, the method may automatically proceed to step 706.

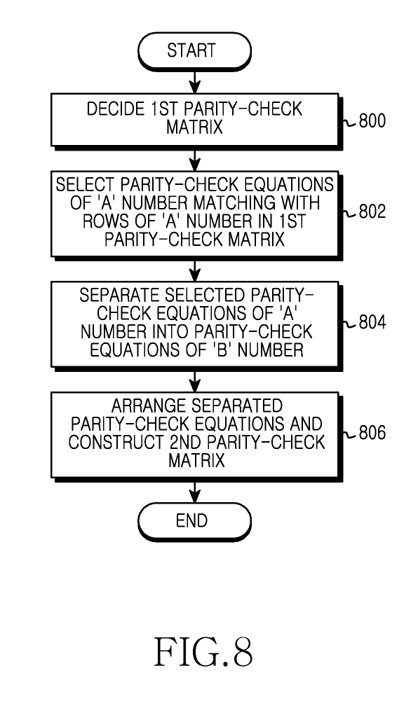

In step 706, the transmitter decides additional parity bits using a 2nd parity-check matrix ‘H_{E}’ that is an extension of the 1st parity-check matrix ‘H₁’. For example, the 1st parity-check matrix ‘H₁’ is extended into the 2nd parity-check matrix ‘H_{E}’ of FIG. 4, and the ‘p=(p₀, p₁, . . . , p₁₉)’ increases to the ‘p=p_{E0}, p_{E1}, . . . , p_{E27)’. The <weight-}1 position sequence conversion process> is described in more detail below with reference to FIG. 8.

In step 708, the transmitter transmits the remnant parity bits, except for the parity bits ‘p=(p₀, p₁, . . . , p₁₉)’ transmitted in step 700.

FIG. 8 is a flowchart illustrating a weight-1 position sequence conversion process according to an embodiment of the present invention.

Referring to FIG. 8, in step 800, a transmitter decides a 1st parity-check matrix ‘H₁’ that is used when there is no request for transmission of additional parity from a receiver. For example, the transmitter considers the parity-check matrix ‘H₁’ being N₁=32, K₁=12, M₁=4, q₁=5 and having a 1st weight-1 sequence as in FIG. 3.

In step 802, the transmitter selects ‘A’ parity-check equations matching with ‘A’ rows of the 1st parity-check matrix ‘H₁’. That is, the transmitter selects a position ‘a₀, a₁, a₂, . . . , a_{F}_{_{IR}}₋₁’ of a row matching with a parity-check equation to be separated in a parity-check matrix corresponding to a 1st weight-1 sequence. Each a₁ value satisfies a relation of 0≦a₀≦a₁≦ . . . a_{F}_{_{IR}}₋₁<q₁.

Here, F_{IR}=N_{IR}/M₁ (where, F_{IR}≦q₁), ‘N_{IR}’ denotes the number of parity-check equations matching with rows of ‘N_{IR}’ number in the 1st parity-check matrix, ‘q₁’ denotes a parameter deciding positions of ‘1’ of the remnant columns from positions of ‘1’ being at a 1st column within each column group in the 1st parity-check matrix, and ‘M₁’ denotes the number of columns included in a column group.

For example, the transmitter considers the parity-check matrix ‘H₁’ being N₁=32, K₁=12, M₁=4, q₁=5 illustrated in FIG. 3 and having the following 1st weight-1 sequence.

$$\begin{matrix}0 & 8 & 12 & 18 \\ 1 & 4 & 14 & \\ 0 & 11 & 17 & \end{matrix}$$

Here, the 1st weight-1 sequence may be expressed as S_{0,0}⁽¹⁾=0, S_{0,1}⁽¹⁾=8, S_{0,2}⁽¹⁾=12, S_{0,3}⁽¹⁾=18, S_{1,0}⁽¹⁾=1, S_{1,1}⁽¹⁾=4, S_{1,2}⁽¹⁾=14, S_{2,0}⁽¹⁾=0, S_{2,1}⁽¹⁾=11, S_{2,2}⁽¹⁾=17. Also, j_{1,max}=4, j_{2,max}=3, j_{3,max}=3 can be easily appreciated.

In step 804, the transmitter separates each of the ‘A’ parity-check equations selected from the 1st parity-check matrix, into ‘B’ parity-check equations. For example, applying the <weight-1 position sequence conversion process> to the parity-check matrix corresponding to the 1st weight-1 position sequence is an equivalent of separating a parity-check equation matching with a (aⱼ+q₁·i)th row of the parity-check matrix corresponding to the 1st weight-1 sequence for a firstly given a₀, a₁, . . . , a_{F}_{_{IR}}₋₁.

In step 806, the transmitter arranges the separated parity-check equations and constructs a 2nd parity-check matrix.

For example, the transmitter considers the three parity-check equations shown in Equation (4). Here, assuming that the transmitter separates parity-check equations matching with the first and second rows of a parity-check matrix, in Equation (4), ‘m₀+m₁+m₂+p₀=0’ is equivalent to ‘m₀+p₀=m₁+m₂’ and ‘m₀+m₁+m₃+p₁=0’ is equivalent to ‘m₀+m₃=m₁+p₁’. Accordingly, the first and second parity-check equations of Equation 4, i.e., m₀+m₁+m₂+p₀=0 and m₀+m₁+m₃+p₁=0, can be expressed as shown in Equation (5) below introducing intermediate variables (y₀, y₁). If Equations (4) and (5) are expressed as parity-check equations regarding each of the intermediate variables (y₀, y₁) as a parity bit, it can be given as in Equation (6). Equation (6) can be expressed as a multiplication of a matrix as shown in Equation (7).

In Equation (7), ‘c_{E}’ is a codeword composed of ‘c’ and ‘y₀, y₁’. Here, a parity-check matrix for the codeword ‘c_{E}’ is ‘H_{E}’. That is, it is equivalent to generating an extended codeword ‘c_{E}32 (c, y₀, y₁)’ in which parity (y₀, y₁) are additionally added to the firstly given codeword ‘c’. Here, from the relationship between the ‘H’ of Equation 1 above and the ‘H_{E}’ of Equation 7 above, it can be appreciated that, when combining the first row and the second row of the ‘H_{E}’, the first row of the ‘H’ is obtained and, when combining the third row and the fourth row of the ‘H_{E}’, the second row of the ‘H’ is obtained. This is the desired result obtained from introducing the intermediate variables (y₀, y₁) into Equations (4) and (5) above. If rows of the parity-check matrix ‘H_{E}’ obtained through the introduction of the intermediate variable are added up, the first given parity-check matrix ‘H’ can be obtained as desired.

However, a process of arranging separated parity-check equations and constructing a 2nd parity-check matrix is replaceable with a process of performing a <weight-1 position sequence conversion algorithm> of deciding a position of ‘1’ in the 2nd parity-check matrix, after deciding the size of a 2nd parity-check matrix as in FIG. 4.

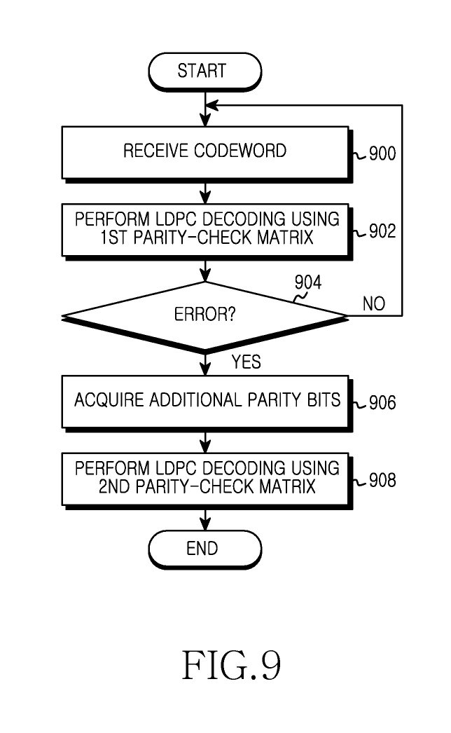

FIG. 9 is a flowchart illustrating a channel decoding method using a linear code based on a parity-check matrix in a communication/broadcasting system using an LDPC code according to an embodiment of the present invention.

Referring to FIG. 9, in step 900, a receiver receives an encoded codeword from a transmitter. In step 902, the receiver performs LDPC decoding using a 1st parity-check matrix.

In step 904, if the receiver identifies that there is an LDPC decoding error, the method proceeds to step 906 and sends a request for transmission of additional parity to the transmitter, receiving additional parity bits from the transmitter, or the receiver may previously store or generate the 1st parity-check matrix and a 2nd parity-check matrix. In this case, the receiver may obtain additional parity bits using the 1st and 2nd parity-check matrixes stored or generated in the receiver, without requesting and receiving the additional parity bits. Alternatively, irrespective of the request from the receiver, the transmitter may transmit the additional parity bits to the receiver, and the receiver may store the additional parity bits transmitted from the transmitter and use, if there occurs a decoding error, the stored additional parity bits without a separate request.

In step 908, the receiver performs LDPC decoding using the 2nd parity-check matrix that is an extension of the 1st parity-check matrix.

Although not illustrated, when a receiver of excellent decoding performance in which performance is not deteriorated even when decoding is performed using rather an extended Nth parity-check matrix than the 1st parity-check matrix, the receiver can omit steps 902, 904, and 906 and just perform the decoding using the Nth parity-check matrix. The Nth parity-check matrix may be acquired from the transmitter or may be previously stored in the receiver. In this case, the transmitter suitably encodes and transmits using the Nth parity-check matrix, or the transmitter encodes using a 1st parity-check matrix and, separately or together with encoded data, transmits additional parity bits generated sequentially up to the Nth parity-check matrix.

Also, even when transmitted data or contents require high decoding performance as premium data or content, the receiver can omit steps 902, 904, and 906 and just perform decoding using an Nth parity-check matrix. That is, when the transmitter encodes and transmits the data or contents as the premium data or content using the Nth parity-check matrix or when the transmitter performs encoding using a 1st parity-check matrix and transmits, separately or together with encoded data, additional parity bits generated sequentially up to the Nth parity-check matrix, the receiver can omit steps 902, 904, and 906 and just perform the decoding using the Nth parity-check matrix or perform the decoding using the additional parity bits generated sequentially up to the Nth parity-check matrix.

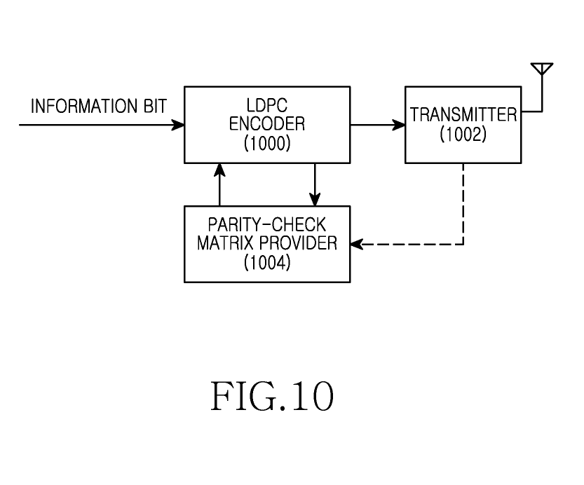

FIG. 10 is a block diagram illustrating a transmitter according to an embodiment of the present invention.

Referring to FIG. 10, an LDPC encoder 1000 performs LDPC encoding using a 1st parity-check matrix or 2nd parity-check matrix provided from a parity-check matrix provider 1004. Here, the LDPC encoding is receiving an input information signal ‘m=(m₀, m₁, . . . , mₖ₋₁)’ and outputting a codeword ‘c’ meeting ‘H·c^{T}=0’ for a parity-check matrix ‘H’.

The parity-check matrix provider 1004 either generates a 2nd parity-check matrix through a 1st parity-check matrix or stores the 1st parity-check matrix and the 2nd parity-check matrix, and provide the 1st parity-check matrix or 2nd parity-check matrix to the LDPC encoder 1000. The parity-check matrix provider 1004 provides additional parity bits generated sequentially up to an Nth parity-check matrix, to the LDPC encoder 1000 or a transmitter 1002. When the 1st parity-check matrix and the generated additional parity bits are simultaneously provided from the parity-check matrix provider 1004 to the LDPC encoder 1000, the LDPC encoder 1000 provides the received 1st parity-check matrix, a codeword generated through an information bit, and the additional parity bits, to the transmitter 1002. The additional parity bits may be arranged and encoded in a different frame or a different region within the same frame.

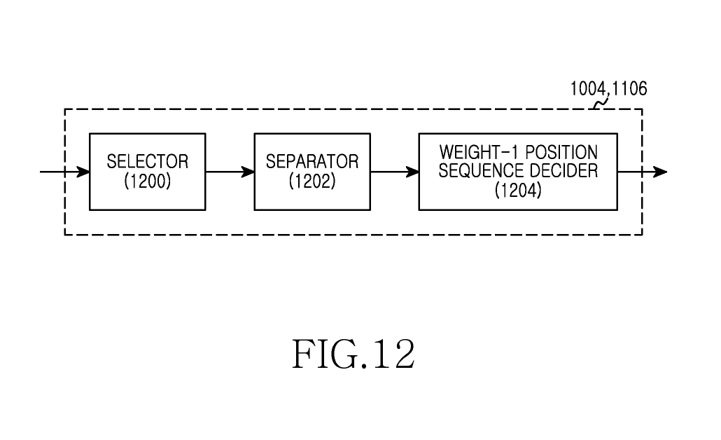

Although not illustrated, the additional parity bits may be provided directly to the transmitter 1002. A process of extending the 1st parity-check matrix and constructing the 2nd parity-check matrix is described in FIG. 12 below.

The transmitter 1002 modulates an encoded bit received from the LDPC encoder 1000 and then, frequency-up converts a baseband signal into a Radio Frequency (RF) signal and transmits the RF signal through an antenna. When the transmitter 1002 receives additional parity bits from the parity-check matrix provider 1004, the transmitter 1002 can transmit the additional parity bits through a different frequency band, a different time or a different frame.

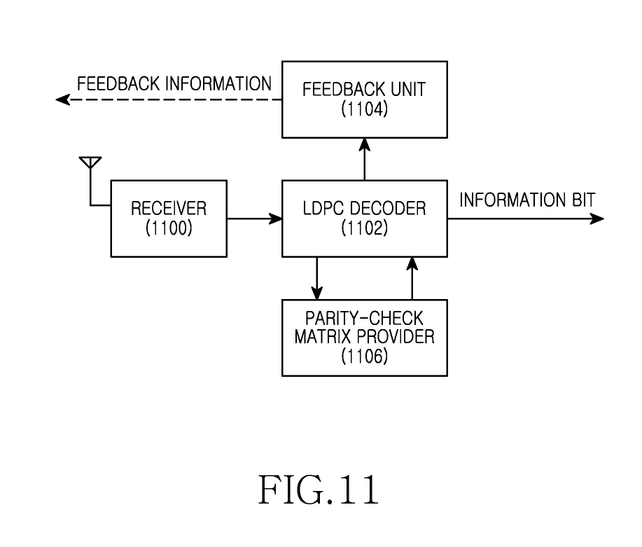

FIG. 11 is a block diagram illustrating a receiver according to an embodiment of the present invention.

Referring to FIG. 11, a receiver 1100 frequency-down converts an RF signal received through an antenna into a baseband signal and demodulates the baseband signal. When additional parity bits are transmitted through a different frequency band, a different time, or a different frame, the receiver 1100 can separately separate the additional parity bits and provide the additional parity bits to an LDPC decoder 1102.

The LDPC decoder 1102 performs decoding associated with encoding performed by the LDPC encoder 1000 of FIG. 10, based on a 1st parity-check matrix or 2nd parity-check matrix provided from a parity-check matrix provider 1106. The LDPC decoder 1102 can be an LDPC decoder disclosed in “Design of Capacity-Approaching Irregular Low-Density Parity-Check Codes” (IEEE TRANSACTIONS ON INFORMATION THEORY, VOL. 47, NO. 2, FEBRUARY 2001) of Thomas J. Richardson and M. Amin Shokrollahi. Also, the LDPC decoder 1102 can perform decoding using additional parity bits provided from the receiver 1100 or the parity-check matrix provider 1106, and a parity-check matrix provided from the parity-check matrix provider 1106.

When the LDPC decoder 1102 performs the decoding associated with the encoding carried out by the LDPC encoder 1000 of FIG. 10, the LDPC decoder 1102 informs the decoding result of a feedback unit 1104. That is, when an error occurs at the time of decoding, when a Negative ACKnowledgement (NACK) signal is normally processed at the time of decoding, the LDPC decoder 1102 provides an ACKnowledgement (ACK) signal to the feedback unit 1104. The feedback unit 1104 transmits an ACK/NACK signal to a transmitter. When reverse transmission is impossible as in most broadcasting standards, the feedback unit 1104 may be omitted.

The parity-check matrix provider 1106 can either generate a 2nd parity-check matrix through a 1st parity-check matrix or store the 1st parity-check matrix and 2nd parity-check matrix, and provides the 1st parity-check matrix or the 2nd parity-check matrix to the LDPC decoder 1102. The parity-check matrix provider 1106 can provide additional parity bits generated sequentially up to an Nth parity-check matrix, to the LDPC decoder 1102.

When the parity-check matrix provider 1106 simultaneously provides the 1st parity-check matrix and the generated additional parity bits to the LDPC decoder 1102, the LDPC decoder 1102 performs decoding using the additional parity bits and the parity-check matrix. When the additional parity bits are arranged and encoded in a different frame or a different region within the same frame, but are not separately provided from the parity-check matrix provider 1106, the additional parity bits can be obtained from the receiver 1100 or the LDPC decoder 1102. A process of extending the 1st parity-check matrix and constructing the 2nd parity-check matrix is described below with reference to FIG. 12.

FIG. 12 illustrates a parity-check matrix provider according to an embodiment of the present invention.

Referring to FIG. 12, a selector 1200 decides a 1st parity-check matrix ‘H₁’ that is used when there is no request for transmission of additional parity. For example, the selector 1200 considers the 1st parity-check matrix ‘H₁’ being N₁=32, K₁=12, M₁=4, q₁=5 and having a 1st weight-1 sequence in FIG. 3.

Also, the selector 1200 selects ‘A’ parity-check equations matching ‘A’ rows in the 1st parity-check matrix. That is, the selector 1200 selects a position ‘a₀, a₁, a₂, . . . , a_{F}_{_{IR}}₋₁’ of a row matching with a parity-check equation to be separated in a parity-check matrix corresponding to a 1st weight-1 sequence. However, each a₁ value satisfies a relation of 0≦a₀≦a₁≦ . . . a_{F}_{_{IR}}₋₁<q₁.

Here, F_{IR}=N_{IR}/M₁ (where, F_{IR}≦q₁), ‘N_{IR}’ denotes the number of parity-check equations matching ‘N_{IR}’ rows in the 1st parity-check matrix, ‘q₁’ denotes a parameter deciding positions of ‘1’ of a 2nd column from positions of ‘1’ being at a 1st column in the 1st parity-check matrix, and ‘M₁’ denotes the number of columns included in a column group.

For example, the selector 1200 considers the parity-check matrix ‘H₁’ being N₁=32, K₁=12, M₁=4, q₁=5 as illustrated in FIG. 3 and having the following 1st weight-1 sequence.

$$\begin{matrix}0 & 8 & 12 & 18 \\ 1 & 4 & 14 & \\ 0 & 11 & 17 & \end{matrix}$$

Here, the 1st weight-1 sequence may be expressed as S_{0,0}⁽¹⁾=0, S_{0,1}⁽¹⁾=8, S_{0,2}⁽¹⁾=12, S_{0,3}⁽¹⁾=18, S_{1,0}⁽¹⁾=1, S_{1,1}⁽¹⁾=4, S_{1,2}⁽¹⁾=14, S_{2,0}⁽¹⁾=0, S_{2,1}⁽¹⁾=11, S_{2,2}⁽¹⁾=17. Also, j_{1,max}=4, j_{2,max}=3, j_{3,max}=3 can be easily appreciated.

A separator 1202 separates each of the ‘A’ parity-check equations selected from the 1st parity-check matrix, into ‘B’ parity-check equations. For example, applying the <weight-1 position sequence conversion process> to the parity-check matrix corresponding to the 1st weight-1 sequence is an equivalent of separating a parity-check equation matching with a (aⱼ+q₁·i)th row of the parity-check matrix corresponding to the 1st weight-1 sequence for a firstly given a₀, a₁, . . . , a_{F}_{_{IR}}₋₁.

The weight-1 position sequence decider 1204 arranges the separated parity-check equations and constructs a 2nd parity-check matrix. For example, the weight-1 position sequence decider 1204 considers the three parity-check equations shown in Equation (4). Here, assuming that the separator 1202 separates parity-check equations matching with the first and second rows of a parity-check matrix, in Equation (4), ‘m₀+m₁+m₂+p₀=0’ is equivalent to ‘m₀+p₀=m₁+m₂’ and ‘m₀+m₁+m₃+p₁=0’ is equivalent to ‘m₀+m₃=m₁+p₁’. Accordingly, the first and second parity-check equations of Equation 4, i.e., m₀+m₁+m₂+p₀=0 and m₀+m₁+m₃+p₁=0, can be expressed as shown in Equation (5) below introducing intermediate variables (y₀, y₁). If Equations (4) and (5) are expressed as parity-check equations regarding each of the intermediate variables (y₀, y₁) as a parity bit, it can be given as in Equation (6). Equation (6) can be expressed as a multiplication of a matrix as shown in Equation (7).

In Equation (7), ‘c_{E}’ is a codeword composed of ‘c’ and ‘y₀, y₁’. Here, a parity-check matrix for the codeword ‘c_{E}’ is ‘H_{E}’, which is equivalent to generating an extended codeword ‘c_{E}=(c, y₀, y₁)’ in which parity (y₀, y₁) are additionally added to the firstly given codeword ‘c’. Here, from the relationship between ‘H’ of Equation (1) above and ‘H_{E}’ of Equation (7), it can be appreciated that, when combining the first row and the second row of ‘H_{E}’, the first row of ‘H’ is obtained and, if combining the third row and the fourth row of ‘H_{E}’, the second row of ‘H’ is obtained. This is the desired result of introducing the intermediate variables (y₀, y₁) in Equations (4) and (5). If rows of the parity-check matrix ‘H_{E}’ obtained through the introduction of the intermediate variable as above are added to each other, the first given parity-check matrix ‘H’ can be obtained as desired.

As described above, the embodiments of the present invention can efficiently support a multiple code rate or a multiple codeword, by modifying a parity-check matrix of a parity-check code or LDPC code and using additional parity-check bits in a communication/broadcasting system using the parity-check code or LDPC code. Also, the embodiments of the present invention have an advantage of reducing encoding/decoding complexity, and increasing a decoding convergence speed, thereby improving performance.

While the present invention has been shown and described with reference to certain embodiments thereof, it will be understood by those skilled in the art that various changes in form and details may be made therein without departing from the spirit and scope of the present invention as defined by the appended claims.

What is claimed is:

1. A method for transmitting by a transmitter in a communication/broadcasting system, the method comprising:
generating a codeword including a first parity bit using a first parity-check matrix;
generating an additional parity bit based on a second parity-check matrix, the second parity-check matrix being an extension of the first parity-check matrix; and
transmitting the codeword and the additional parity bit.

2. The method of claim 1, wherein the additional parity bit is a remnant parity bit, except for the first parity bit, from a second parity bit determined based on the second parity-check matrix.

3. The method of claim 1, wherein generating the additional parity bit further comprises:
extending the first parity-check matrix;
selecting at least one parity-check equation corresponding to a parity-check equation from the first parity-check matrix;
separating each of the selected at least one parity-check equation into at least two parity-check equations;
arranging the at least two separated parity-check equations; and
constructing the second parity-check matrix.

4. The method of claim 3, wherein a combination of the separated at least two parity-check equations is consistent with a corresponding row of the first parity-check matrix.

5. The method of claim 3, wherein, when the at least two separated parity-check equations are arranged, an intermediate variable corresponding to the additional parity bit is generated.

6. The method of claim 5, wherein the intermediate variable is generated based on a number of rows matching with the at least one parity-check equation selected from the first parity-check matrix and a number of parity-check equations into which each of the selected parity-check equations is separated.

7. The method of claim 3, wherein the second parity-check matrix is decided by deciding a size of the second parity-check matrix to be greater than a size of the first parity-check matrix, and rearranging a weight-1 position of the first parity-check matrix in the second parity-check matrix through a weight-1 position sequence conversion algorithm.

8. The method of claim 7, wherein the size of the second parity-check matrix is decided based on a number of rows corresponding to the parity-check equations selected from the first parity-check matrix and a number of parity-check equations into which each of the selected parity-check equations is separated.

9. The method of claim 7, wherein, when ‘N_{IR}’ rows matching with the parity-check equations selected from the first parity-check matrix are each separated into two parity-check equations, the weight-1 position sequence conversion algorithm uses an algorithm below,
For 0 ≦ l < F_{IR}
TEMP=0
aₗ ← (aₗ + l)
For 0 ≦ i < K₁ / M₁
For 0 ≦ j < j_{i,max}
If (S_{i,j}⁽¹⁾ > aₗ + q₁ (M₁ − 1))
S_{i,j}⁽²⁾ ← S_{i,j}⁽¹⁾ + M₁
```
  END
  For 0 ≦ k < M₁
  If (S_{i,j}⁽¹⁾ > aₗ + q₁ (k − 1)) & &(S_{i,j}⁽¹⁾ ≦ aₗ + q₁ · k)
```
& &((S_{i,j}⁽¹⁾%q₁) ≠ aₗ)
S_{i,j}⁽²⁾ ← S_{i,j}⁽¹⁾ + k
END
Else If (S_{i,j}⁽¹⁾ > aₗ + q₁ (k − 1)) & &(S_{i,j}⁽¹⁾ ≦ aₗ + q₁ · k)
& &((S_{i,j}⁽¹⁾%q₁) = aₗ)
S_{i,j}⁽²⁾ ← S_{i,j}⁽¹⁾ + k + Temp
Temp←((Temp+1)%2)
END
END
END
```
  END
  For 0 ≦ i < k₁ / M₁
```
For 0 ≦ j < j_{i,max}
S_{i,j}⁽¹⁾ ← S_{i,j}⁽²⁾
END
END
q₁ ← (q₁ + 1)
END
where,
‘a₀, a₁, a₂, . . . , a_{F}_{_{IR}}₋₁’ is a position of a row matching with the parity-check equation to be separated in the first parity-check matrix,
each of ‘aₗ’ values satisfies a relation of ‘0≦a₀≦a₁≦ . . . ≦a_{F}_{_{IR}}₋₁<q₁’,
‘K₁’ is an information word length,
‘M₁’ is a column group unit,
‘q_{E}’ is a parameter deciding a position of ‘1’ within a corresponding column group of the second parity-check matrix and is given as ‘q_{E}=(N_{E}−K₁)/M₁’,
‘F_{IR}’ is a parameter for guaranteeing that ‘q_{E}’ is an integer and satisfies ‘F_{IR}=N_{IR}/M₁, F_{IR}≦q₁’ in which ‘q₁’ is a parameter deciding a position of ‘1’ within a corresponding column group of the first parity-check matrix,
‘S_{i,j}⁽¹⁾’ is a j th numeral of an i th sequence in the first parity-check matrix,
‘S_{i,j}⁽²⁾’ represents a j th numeral of an i th sequence in the second parity-check matrix,
‘j_{i,max}’ is the number of numerals in the i th sequence,
‘%’ is the remnant operation, and
‘&&’ is AND operation.

10. The method of claim 1, wherein the communication/broadcasting system utilizes a Low Density Parity Check (LDPC) code.

11. A method for receiving by a receiver in a communication/broadcasting system, the method comprising:
receiving a codeword from a transmitter; and
decoding the codeword based on a first parity-check matrix and an additional parity bit,
wherein the additional parity bit is based on a second parity-check matrix, the second parity-check matrix being an extension of the first parity-check matrix.

12. The method of claim 11, wherein the additional parity bit is a remnant parity bit, except for a first parity bit from a second parity bit, and
wherein the second parity bit is decided based on the second parity-check matrix.

13. The method of claim 11, wherein the communication/broadcasting system utilizes a Low Density Parity Check (LDPC) code.

14. An apparatus for transmitting in a communication/broadcasting system, the apparatus comprising:
a parity-check matrix provider for extending a first parity-check matrix and deciding a second parity-check matrix;
an encoder for generating a codeword including a first parity bit utilizes the first parity-check matrix, and deciding a second parity bit based on the second parity-check matrix, to generate an additional parity bit; and
a transmitter for transmitting the generated codeword and the additional parity bit.

15. The apparatus of claim 14, wherein the second parity bit includes the 1st parity bit, and
wherein the additional parity bit is a remnant parity bit, except for the first parity bit, from the second parity bit.

16. The apparatus of claim 14, wherein the parity-check matrix provider further comprises:
a selector for selecting at least one parity-check equation corresponding to a parity-check equation from the first parity-check matrix;
a separator for separating each of the selected at least one parity-check equation into at least two parity-check equations; and
a weight-1 position sequence decider for arranging the separated at least two parity-check equation and constructing the second parity-check matrix.

17. The apparatus of claim 16, wherein a combination of the separated at least two parity-check equations is consistent with a corresponding row of the first parity-check matrix.

18. The apparatus of claim 16, wherein, when the separated at least two parity-check equations are arranged, an intermediate variable corresponding to the additional parity bit is generated.

19. The apparatus of claim 18, wherein the intermediate variable is decided based on a number of rows matching with the parity-check equations selected from the first parity-check matrix and a number of parity-check equations into which each of the selected at least two parity-check equations is separated.

20. The apparatus of claim 14, wherein the parity-check matrix provider decides a size of the second parity-check matrix to be greater than a size of the first parity-check matrix, and rearranges a weight-1 position of the first parity-check matrix in the second parity-check matrix through a weight-1 position sequence conversion algorithm.

21. The apparatus of claim 20, wherein a size of the second parity-check matrix is decided based on a number of rows corresponding to the parity-check equations selected from the first parity-check matrix and a number of parity-check equations into which each of the selected parity-check equations is separated.

22. The apparatus of claim 21, wherein, when ‘N_{IR}’ rows matching with the parity-check equations selected from the first parity-check matrix are each separated into two parity-check equations, the weight-1 position sequence conversion algorithm uses an algorithm below,
For 0 ≦ l < F_{IR}
TEMP=0
aₗ ← (aₗ + l)
For 0 ≦ i < K₁ / M₁
For 0 ≦ j < j_{i,max}
If (S_{i,j}⁽¹⁾ > aₗ + q₁ (M₁ − 1))
S_{i,j}⁽²⁾ ← S_{i,j}⁽¹⁾ + M₁
END
For 0 ≦ k < M₁
If (S_{i,j}⁽¹⁾ > aₗ + q₁ (k − 1)) & &(S_{i,j}⁽¹⁾ ≦ aₗ + q₁ · k)
& &((S_{i,j}⁽¹⁾%q₁) ≠ aₗ)
S_{i,j}⁽²⁾ ← S_{i,j}⁽¹⁾ + k
END
Else If (S_{i,j}⁽¹⁾ > aₗ + q₁ (k − 1)) & &(S_{i,j}⁽¹⁾ ≦ aₗ + q₁ · k)
& &((S_{i,j}⁽¹⁾%q₁) = aₗ)
S_{i,j}⁽²⁾ ← S_{i,j}⁽¹⁾ + k + Temp
Temp←((Temp+1)%2)
END
END
END
```
  END
  For 0 ≦ i < k₁ / M₁
```
For 0 ≦ j < j_{i,max}
S_{i,j}⁽¹⁾ ← S_{i,j}⁽²⁾
END
```
  END
  q₁ ← (q₁ + 1)
```
END
where,
‘a₀, a₁, a₂, . . . , a_{F}_{_{IR}}₋₁’ is a position of a row matching with the parity-check equation to be separated in the first parity-check matrix,
each of ‘aₗ’ values satisfies a relation of ‘0≦a₀≦a₁≦a_{F}_{_{IR}}₋₁<q₁’,
‘K₁’ is an information word length,
‘M₁’ is a column group unit,
‘q_{E}’ is a parameter deciding a position of ‘1’ within a corresponding column group of the second parity-check matrix and is given as ‘q_{E}=(N_{E}−K₁)/M₁’,
F_{IR} is a parameter for guaranteeing that ‘q_{E}’ is an integer and satisfies ‘F_{IR}=N_{IR}/M₁, F_{IR}≦q₁’ in which ‘q₁’ is a parameter deciding a position of ‘1’ within a corresponding column group of the first parity-check matrix,
‘S_{i,j}⁽¹⁾’ is a j th numeral of an i th sequence in the 1st parity-check matrix,
‘S_{i,j}⁽²⁾’ represents a j th numeral of an i th sequence in the second parity-check matrix,
‘j_{i,max}’ is the number of numerals in the i th sequence,
‘%’ is a remnant operation, and
‘&&’ is AND operation.

23. The apparatus of claim 14, wherein the communication/broadcasting system utilizes a Low Density Parity Check (LDPC) code.

24. An apparatus for receiving in a communication/broadcasting system, the apparatus comprising:
a receiver for receiving a codeword including a first parity bit from a transmitter; and
a decoder for decoding the codeword based on a first parity-check matrix and an additional parity bit.

25. The apparatus of claim 24, wherein the additional parity bit is decided based on a second parity-check matrix, the second parity-check matrix being an extension of the first parity-check matrix, and the additional parity is a remnant parity bit, except for the first parity bit, from a second parity bit from the second parity-check matrix.

26. The apparatus of claim 24, wherein the communication/broadcasting system utilizing a Low Density Parity Check (LDPC) code.
